(19) United States
(12) Patent Application Publication
(10) Pub. No.: US 2013/0241363 A1
(43) Pub. Date: Sep. 19, 2013

(54) METHOD OF MANUFACTURING RESONATOR ELEMENT, METHOD OF MANUFACTURING RESONATOR, RESONATOR, OSCILLATOR, AND ELECTRONIC APPARATUS

(71) Applicant: SEIKO EPSON CORPORATION, Tokyo (JP)

(72) Inventor: Junji KOBAYASHI, Minamiminowa (JP)

(73) Assignee: SEIKO EPSON CORPORATION, Tokyo (JP)

(21) Appl. No.: 13/799,368

(22) Filed: Mar. 13, 2013

(30) Foreign Application Priority Data
Mar. 15, 2012 (JP) 2012-059329

(51) Int. Cl. H01L 41/332; H01L 41/08

(52) U.S. Cl. CPC H01L 41/332; H01L 41/08
USPC 310/368; 216/13; 29/25.35

(57) ABSTRACT

A method of manufacturing a resonator element includes a process of forming a mesa substrate by disposing a first mask on a principal surface located on a +Y′-axis side of the quartz crystal substrate, disposing a second mask on a principal surface located on a −Y′-axis side so as to be located at a position shifted toward a +Z′-axis side from the first mask, and etching the quartz crystal substrate via the first and second masks, the mesa substrate including a vibrating section including a first protruding section protruding toward the +Y′-axis side from the quartz crystal substrate and a second protruding section protruding toward the −Y′-axis side, and a small-thickness section disposed along an outer edge of the vibrating section and having a thickness smaller than a thickness of the vibrating section.

### BACKGROUND

1. Technical Field

The present invention relates to a method of manufacturing a resonator element, a method of manufacturing a resonator, a resonator, an oscillator, and an electronic apparatus.

2. Related Art

In the past, there has been known a resonator element (a resonator and an oscillator) using a quartz crystal. Such a resonator element is superior in the frequency-temperature characteristic, and is therefore widely used as a reference frequency source and an oscillation source of a variety of electronic apparatuses. In particular, a resonator element using a quartz crystal substrate carved out at a cutting angle called AT cut has a frequency-temperature characteristic showing a cubic curve, and is therefore widely used also for mobile communication equipment such as a cellular phone (see, e.g., JP-A-2010-147625 (Document 1)).

As disclosed in Document 1, as the resonator element using the AT-cut quartz crystal substrate, a resonator element having a structure called bi-mesa structure is known to the public. The bi-mesa structure denotes a shape having a vibrating section with a large thickness and a small-thickness section disposed along an outer edge of the vibrating section and thinner than the vibrating section wherein the vibrating section has a first protruding section protruding from the small-thickness section toward a +Y′-axis side, and a second protruding section protruding toward a −Y′-axis side. Since the vibration can efficiently be confined in the vibrating section, such a shape has an advantage that a superior vibration characteristic can be obtained.

Here, as a method of forming the bi-mesa-structure quartz crystal substrate, there can be cited a method of, for example, patterning a plate-like quartz crystal substrate using a photolithography technique and an etching technique.

Specifically, the plate-like quartz crystal substrate carved out with AT-cut is firstly prepared, and a first mask corresponding to the first protruding section is formed on one surface of the quartz crystal substrate, and a second mask corresponding to the second protruding section is formed on the other surface thereof. It should be noted that it is assumed that the first and second masks have the same shape, and are formed to have the respective contours overlapping each other. Subsequently, the quartz crystal substrate is etched on the both sides thereof via the first and second masks to thereby form a quartz crystal substrate having the vibration section with the first and second protruding sections and a peripheral edge section located in the periphery of the vibration section. Then, by forming electrodes on the surface of the quartz crystal substrate, the quartz crystal resonator element can be obtained.

Here, in some cases, a relative shift between the first mask and the second mask occurs in the etching process of the quarts crystal substrate, and the quartz crystal resonator element having the shape shown in FIG. 14 is manufactured depending on how the relative shift occurs. It should be noted that due to the crystal face of the quartz crystal, a side surface 512 on a +Z′-axis side of the first protruding section 51 becomes a surface roughly perpendicular to a principal surface 511, and a side surface 513 on a −Z′-axis side thereof becomes a surface oblique to the principal surface 511. Further, a side surface 522 on a −Z′-axis side of the second protruding section 52 becomes a surface roughly perpendicular to a principal surface 521, and a side surface 523 on a +Z′-axis side thereof becomes a surface oblique to the principal surface 521.

Here, since the width (the length in the Z′-axis direction) of an effective vibrating region 53 of a mesa part is important for controlling the vibration characteristics (quality) of the quartz crystal resonator element, it is necessary to obtain and then control the width. It should be noted that the effective vibrating region 53 denotes a region where the principal surface 511 of the first protruding section 51 and the principal surface 521 of the second protruding section 52 overlap each other.

There are various methods for obtaining the width W1′ of the effective vibrating region 53 in the shape shown in FIG. 14. As a relatively easy method, it is possible to obtain the width W1′ of the effective vibrating region 53 by, for example, obtaining the total width W2′ of the quartz crystal resonator element, a distance L1′ between an end A2′ on the −Z′-axis side of the principal surface 511 of the first protruding section 51 and an end B2′ on the −Z′-axis side of the quartz crystal resonator element, and a distance L2′ between an end A4′ on the +Z′-axis side of the principal surface 521 of the second protruding section 52 and an end B1′ on the +Z′-axis side of the quartz crystal resonator element, and then substituting the values to the following formula.

W1′=W2′−(L1′+L2′)

However, in the configuration shown in FIG. 14, there is a problem that it is not achievable to accurately measure the distances L1′, L2′. Specifically, in the case of measuring the distance L1′, it is necessary to observe the quartz crystal resonator element from the Y′ direction to identify the end A2′ of the principal surface 511 of the first protruding section 51. However, since a boundary C3′ between the side surface 513 of the first protruding section 51 and the peripheral part is located next to the end A2′, the two boundary lines parallel to each other are observed extremely close to each other, and might be observed integrally, and therefore it is not achievable to accurately identify the end A2′. Therefore, it is not achievable to accurately measure the distance L1′. The same applies to the measurement of the distance L2′.

As described above, in the method of manufacturing the quartz crystal resonator element according to the related art, there is a problem that there is manufactured the quartz crystal resonator element having the effective vibrating region the width of which cannot accurately be measured, and having the vibration characteristics (the quality) difficult to control.

JP-A-2008-067345 is an example of a related art document.

### SUMMARY

An advantage of some aspects of the invention is to provide a method of manufacturing a resonator element having the effective vibrating region of the vibrating section the width of which can easily and accurately be measured, and having the vibration characteristics easy to control, a method of manufacturing a resonator having the vibration characteristics easy to control, a resonator, an oscillator, and an electronic apparatus each superior in reliability and equipped with the resonator element.

The invention can be implemented as the following application examples.

### Application Example 1

This application example of the invention is directed to a method of manufacturing a resonator element including: providing a rotated Y-cut quartz crystal substrate, forming a mesa substrate by disposing a first mask on a principal surface located on a +Y′-axis side of the quartz crystal substrate, disposing a second mask on a principal surface located on a −Y′-axis side so as to be located at a position shifted toward a +Z′-axis side from the first mask, and etching the quartz crystal substrate via the first mask and the second mask, the mesa substrate including a vibrating section including a first protruding section protruding toward the +Y′-axis side from the quartz crystal substrate and a second protruding section protruding toward the −Y′-axis side, and a small-thickness section disposed along an outer edge of the vibrating section and having a thickness smaller than a thickness of the vibrating section, and providing a conductive pattern to the mesa substrate.

Thus, the width of the effective vibrating region of the vibrating section can easily and accurately be measured, and it is possible to manufacture the resonator element the vibration characteristics of which can easily be controlled.

### Application Example 2

In the method of manufacturing a resonator element according to the above application example of the invention, it is preferable that an end on the +Z′-axis side of the first mask is located on the +Z′-axis side with respect to a center of the mesa substrate in a Z′-axis direction, and an end on the −Z′-axis side of the second mask is located on the −Z′-axis side with respect to the center of the mesa substrate in the Z′-axis direction.

Thus, it is possible to form the effective vibrating region, in which the principal surface of the first protruding section and the principal surface of the second protruding section overlap each other, in the central portion of the resonator element in the Z′-axis direction while keeping the effective vibrating region relatively large in size. Therefore, it is possible to vibrate the vibrating section in a balanced manner, and thus the resonator element superior in vibration characteristics can be manufactured.

### Application Example 3

In the method of manufacturing a resonator element according to the above application examples of the invention, it is preferable that assuming that a shift amount in the Z′-axis direction between the first mask and the second mask is D, and a sum of a height of the principal surface of the first protruding section from a principal surface on the +Y′-axis side of the small-thickness section and a height of the principal surface of the second protruding section from a principal surface on the −Y′-axis side of the small thickness section is t, a relationship between the shift amount D and the sum t satisfies 0<D≦t/2.

Thus, it is possible to keep the size of the effective vibrating region relatively large.

### Application Example 4

In the method of manufacturing a resonator element according to the above application examples of the invention, it is preferable that a side surface connecting the end on the +Z′-axis side of the principal surface of the first protruding section and the small-thickness section to each other is perpendicular to the principal surface of the first protruding section, and a side surface connecting the end on the −Z′-axis side of the principal surface of the second protruding section and the small-thickness section to each other is perpendicular to the principal surface of the second protruding section.

Thus, the width of the effective vibrating region of the vibrating section can accurately be measured.

### Application Example 5

In the method of manufacturing a resonator element according to the above application examples of the invention, it is preferable that the quartz crystal substrate is an AT-cut quartz crystal substrate.

Thus, the resonator element having superior frequency characteristics can be manufactured.

### Application Example 6

It is preferable that the method of manufacturing a resonator according to the above application example of the invention includes housing the resonator element, which is manufactured using the method of manufacturing a resonator element according to the above application examples, in a package.

Thus, the resonator having excellent reliability can be obtained.

### Application Example 7

This application example of the invention is directed to a resonator element including a rotated Y-cut quartz crystal substrate including a vibrating section including a first protruding section protruding toward a +Y′-axis side and a second protruding section protruding toward a −Y′-axis side, and a small-thickness section disposed along an outer edge of the vibrating section and having a thickness smaller than a thickness of the vibrating section, and a conductive pattern provided to the quartz crystal substrate, an end on a +Z′-axis side of a principal surface of the first protruding section is disposed so as to overlap a principal surface of the second protruding section in a plan view in a Y′-axis direction, and an end on a −Z′-axis side of the principal surface of the second protruding section overlaps the principal surface of the first protruding section in the plan view in the Y′-axis direction.

Thus, the width of the effective vibrating region of the vibrating section can easily and accurately be measured, and it is possible to obtain the resonator element the vibration characteristics of which can easily be controlled.

### Application Example 8

This application example of the invention is directed to a resonator including the resonator element according to the above application example of the invention, and a package adapted to house the resonator element.

Thus, the resonator having excellent reliability can be obtained.

### Application Example 9

This application example of the invention is directed to an oscillator including the resonator element according to the above application example of the invention, and an oscillation circuit electrically connected to the resonator element.

Thus, the oscillator having excellent reliability can be obtained.

### Application Example 10

This application example of the invention is directed to an electronic apparatus including the resonator element according to the above application example of the invention.

Thus, the electronic apparatus having excellent reliability can be obtained.

### BRIEF DESCRIPTION OF THE DRAWINGS

The invention will be described with reference to the accompanying drawings, wherein like numbers reference like elements.

FIG. 1 is a plan view of a resonator according to a first embodiment of the invention.

FIG. 2 is a cross-sectional view along the A-A line in FIG. 1.

FIGS. 3A and 3B are plan views of a resonator element provided to the resonator shown in FIG. 1, wherein FIG. 3A is a top view and FIG. 3B is a bottom view.

FIG. 4 is a cross-sectional view along the B-B line in FIG. 1.

FIGS. 5A and 5B are partial enlarged views of the resonator element provided to the resonator shown in FIG. 1, wherein FIG. 5A is a top enlarged view and FIG. 5B is a bottom enlarged view.

FIGS. 6A through 6C are cross-sectional views for explaining a method of manufacturing the resonator element shown in FIGS. 3A and 3B.

FIG. 7 is a cross-sectional view for explaining the method of manufacturing the resonator element shown in FIGS. 3A and 3B.

FIG. 8 is a cross-sectional view of a resonator according to a second embodiment of the invention.

FIG. 9 is a cross-sectional view of a resonator according to a third embodiment of the invention.

FIG. 10 is a cross-sectional view showing an example of an oscillator according to an embodiment of the invention.

FIG. 11 is a diagram showing an electronic apparatus (a laptop personal computer) equipped with the resonator element according to an embodiment of the invention.

FIG. 12 is a diagram showing an electronic apparatus (a cellular phone) equipped with the resonator element according to an embodiment of the invention.

FIG. 13 is a diagram showing an electronic apparatus (a digital still camera) equipped with the resonator element according to an embodiment of the invention.

FIG. 14 is a cross-sectional view for explaining the related art.

### DESCRIPTION OF EXEMPLARY EMBODIMENTS

Hereinafter, a method of manufacturing a resonator element, a method of manufacturing a resonator, a resonator, an oscillator, and an electronic apparatus according to the invention will be explained in detail based on the preferred embodiments shown in the accompanying drawings.

Firstly, the resonator (the resonator according to the invention) to which the resonator element according to the invention is applied will be explained.

### First Embodiment

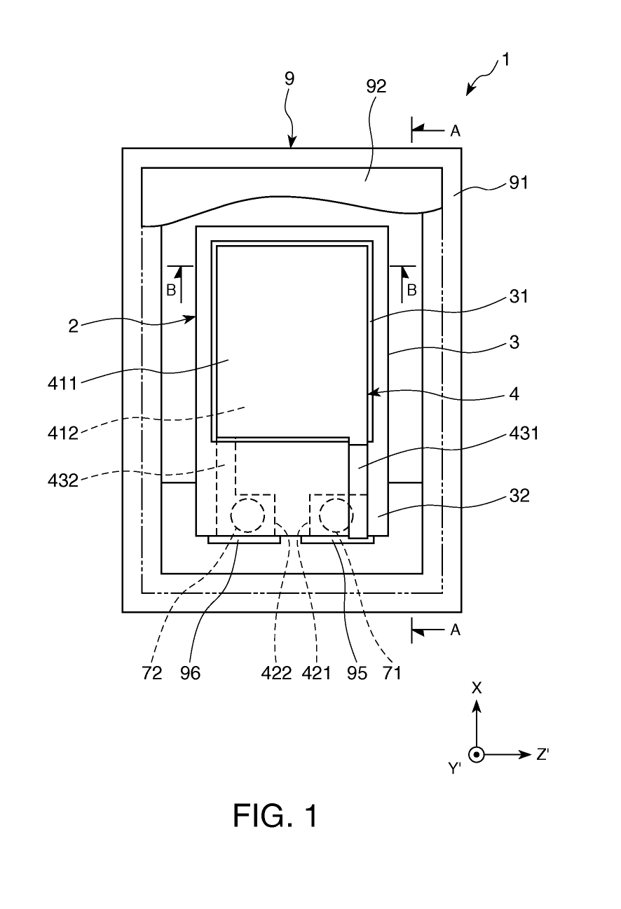

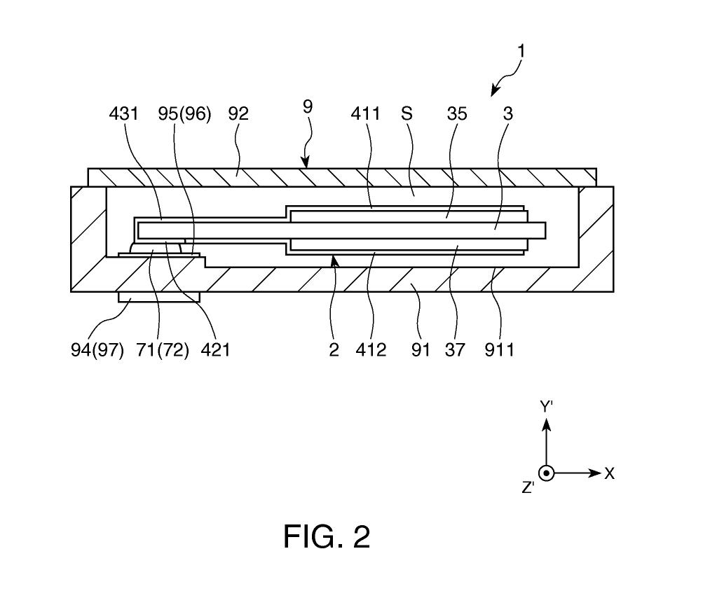

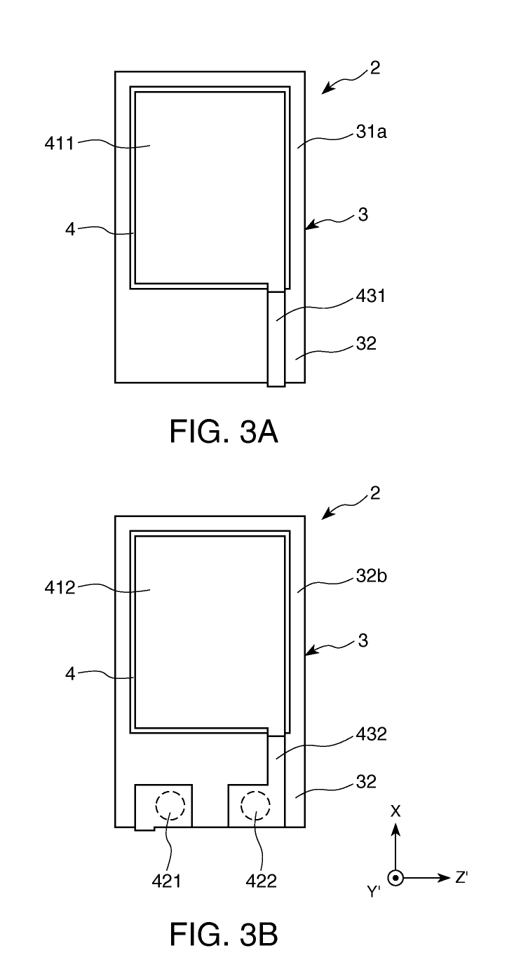

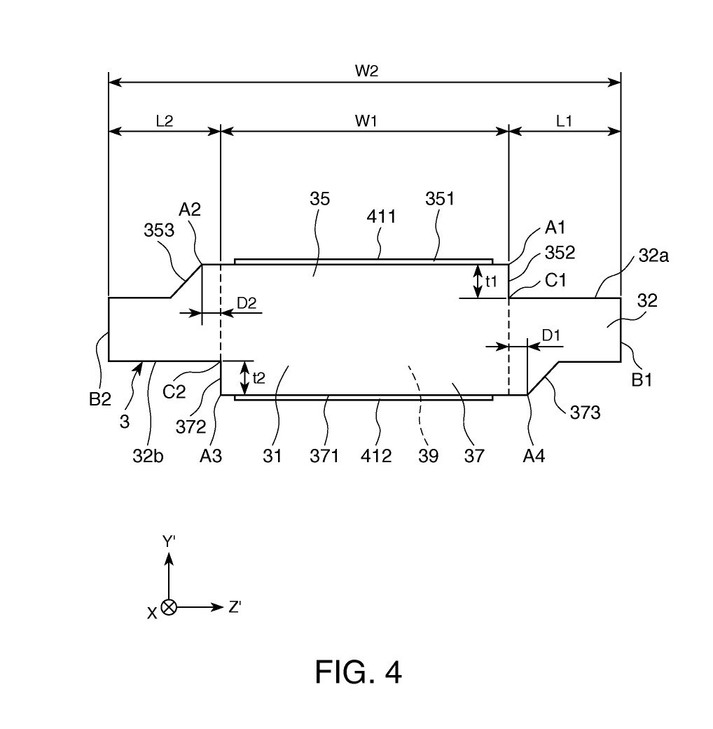

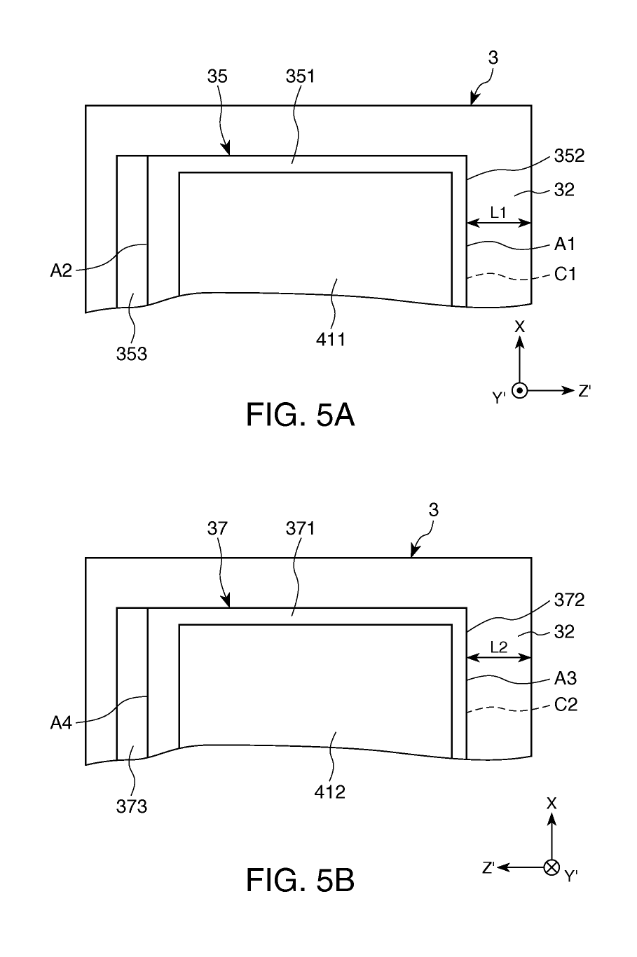

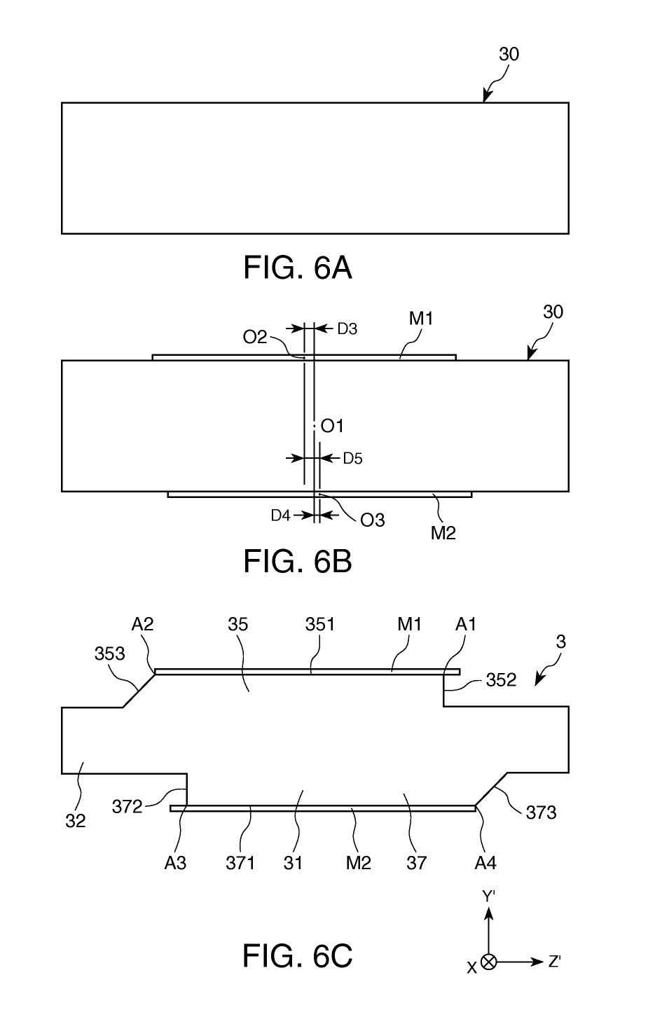

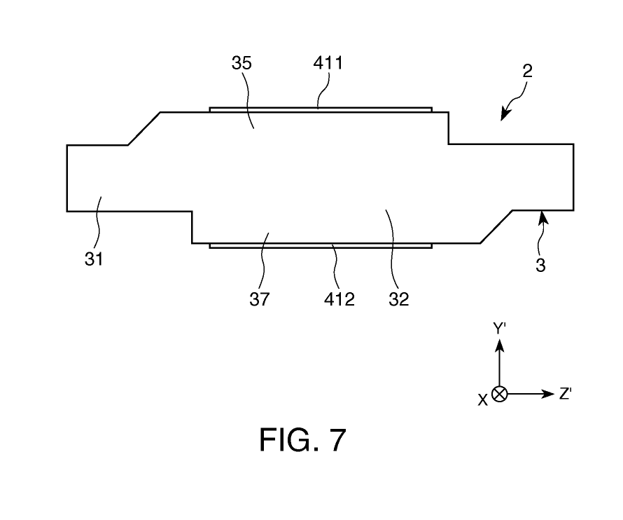

FIG. 1 is a plan view of the resonator according to a first embodiment, FIG. 2 is a cross-sectional view along the A-A line in FIG. 1, FIGS. 3A and 3B are plan views of the resonator element provided to the resonator shown in FIG. 1, wherein FIG. 3A is a top view and FIG. 3B is a bottom view, FIG. 4 is a cross-sectional view along the B-B line in FIG. 1, FIGS. 5A and 5B are partial enlarged views of the resonator element provided to the resonator shown in FIG. 1, wherein FIG. 5A is a top enlarged view and FIG. 5B is a bottom enlarged view, and FIGS. 6A through 6C, and 7 are cross-sectional views for explaining the method of manufacturing the resonator element shown in FIGS. 3A and 3B. It should be noted that the upper side of FIG. 2 is referred to as an “upper side” and the lower side thereof is referred to as a “lower side” in the following descriptions for the sake of convenience of explanation.

### 1. Resonator

The resonator 1 shown in FIGS. 1 and 2 has a resonator element 2 (the resonator element according to the embodiment of the invention) and a package 9 housing the resonator element 2. Hereinafter, the resonator element 2, and the package 9 will sequentially be explained in detail.

### Package

The package 9 has a base 91 having a box shape provided with a recessed section 911 opened upward, and a lid 92 having a plate shape and bonded to the base 91 so as to block the opening of the recessed section 911. Such a package 9 has a housing space S formed by the recessed section 911 blocked by the lid 92, and the resonator element 2 is airtightly housed and installed in the housing space S. It should be noted that the housing space S can be kept in, for example, a reduced-pressure (preferably vacuum) state, or filled with an inert gas such as nitrogen, helium, or argon. Thus, the vibration characteristics of the resonator element 2 can be improved.

The constituent material of the base 91 is not particularly limited, but a variety of types of ceramics such as aluminum oxide can be used therefor. Further, the constituent material of the lid 92 is not particularly limited, but a member with a linear expansion coefficient similar to that of the constituent material of the base 91 is preferable. For example, if the ceramics described above is used as the constituent material of the base 91, an alloy such as kovar is preferably used. It should be noted that bonding between the base 91 and the lid 92 is not particularly limited, but it is possible to adopt bonding with an adhesive, or to adopt bonding with seam welding.

The bottom surface of the recessed section 911 is provided with a first connection terminal 95 and a second connection terminal 96. The first connection terminal 95 is formed so as to be opposed to a first connection electrode 421 described later provided to the resonator element 2, and the first connection terminal 95 and the first connection electrode 421 are electrically connected to each other via an electrically conductive fixation member 71. Further, the second connection terminal 96 is formed so as to be opposed to a second connection electrode 422 described later provided to the resonator element 2, and the second connection terminal 96 and the second connection electrode 422 are electrically connected to each other via an electrically conductive fixation member 72.

The electrically conductive fixation members 71, 72 are not particularly limited, but solder, silver paste, an electrically conductive adhesive (an adhesive obtained by dispersing electrically conductive filler such as metal particles in a resin material), and so on can be used therefor.

Further, the first connection terminal 95 is electrically connected to an external terminal (a mounting terminal) 94 provided to the bottom surface of the package 9 via a through hole not shown, and the second connection terminal is electrically connected to an external terminal (a mounting terminal) 97 provided to the bottom surface of the package 9 via a through hole not shown.

The configurations of the first and second connection terminals 95, 96 and the external terminals 94, 97 are not particularly limited providing each of the configurations has an electrical conductivity, but each of the terminals can be formed of a metal coating obtained by stacking a coat made of, for example, Ni (nickel), Au (gold), Ag (silver), or Cu (copper) on a metalization layer (a foundation layer) made of, for example, Cr (chromium), or W (tungsten).

### Resonator Element 2

As shown in FIGS. 1, 2, 3A, and 3B, the resonator element 2 according to the present embodiment is composed of a quartz crystal substrate 3, and a conductive pattern 4 formed on the quartz crystal substrate 3.

The quartz crystal substrate 3 is a so-called rotated Y-cut quartz crystal substrate vibrating with a vibration mode of a thickness-shear vibration, and is formed of, for example, an AT-cut quartz crystal substrate. Thus, the resonator element 2 capable of exerting superior frequency characteristics can be obtained. It should be noted that the rotated Y-cut quartz crystal substrate denotes the quartz crystal substrate carved out so as to have a principal surface (a principal surface including the X-axis and the Z′-axis) obtained by rotating the plane (the Y-plane) including the X-axis (electrical axis) and the Z-axis (optical axis) as the crystal axes of the quartz crystal around the X axis counterclockwise (in a −Y-axis (the mechanical axis) direction) by a predetermined angle α from the Z axis. In the quartz crystal substrate 3 with such a configuration, it is possible to determine that the longitudinal direction of the quartz crystal substrate 3 is the X axis, the direction along the shorter side thereof is the Z′ axis, and the thickness direction thereof is the Y′ axis. In the case of the AT-cut quartz crystal substrate, the angle α is about 35°15′.

Such a quartz crystal substrate 3 has a vibrating section 31 with a large thickness, and a peripheral section (a small-thickness section) 32 with a small thickness formed in the periphery of the vibrating section 31. The vibrating section 31 has a first protruding section 35 protruding from the peripheral section 32 toward the +Y′-axis side, and a second protruding section 37 protruding toward the −Y′-axis side. In other words, the quartz crystal substrate 3 forms the bi-mesa structure having the mesa sections formed on the both sides. According to such a shape, since the vibration can effectively be confined in the vibrating section 31, the frequency characteristics such as a CI value and a Q value can be improved.

The principal surface 351 of the first protruding section 35 is provided with a first excitation electrode 411, and the principal surface 371 of the second protruding section 37 is provided with a second excitation electrode 412. It should be noted that the first excitation electrode 411 and the second excitation electrode 412 are formed so as to have the respective contours overlapping each other in a plan view of the resonator element 2.

Further, the lower surface of the peripheral section 32 is provided with the first connection electrode 421 and the second connection electrode 422 formed side by side. The first excitation electrode 411 is electrically connected to the first connection electrode 421 via a first connection wiring line 431 formed on the upper surface and a side surface of the quartz crystal substrate 3, and the second excitation electrode 412 is electrically connected to the second connection electrode 422 via a second connection wiring line 432 formed on the lower surface of the quartz crystal substrate 3.

The first excitation electrode 411, the second excitation electrode 412, the first connection electrode 421, the second connection electrode 422, the first connection wiring line 431 and the second connection wiring line 432 described above constitute a conductive pattern 4.

The configurations of the first and second excitation electrodes 411, 412, the first and second connection electrodes 421, 422, and the first and second connection wiring lines 431, 432 are not particularly limited providing each of the configurations has an electrical conductivity, but each of these members can be formed of a metal coating obtained by stacking an electrode layer made of, for example, Ni (nickel), Au (gold), Ag (silver), or Cu (copper) on a metalization layer (a foundation layer) made of, for example, Cr (chromium), or W (tungsten).

Such a resonator element 2 as described above is supported by the electrically conductive fixation members 71, 72 to the package 9. Specifically, as described above, the first connection electrode 421 is fixed to the first connection terminal 95 via the electrically conductive fixation member 71, and the second connection electrode 422 is fixed to the second connection terminal 96 via the electrically conductive fixation member 72.

Then, the shape of the vibrating section 31 will be explained in detail with reference to FIG. 4. FIG. 4 is a cross-sectional view along the B-B line in FIG. 1.

As shown in FIG. 4, the first protruding section 35 has a principal surface 351, a side surface 352 located on the +Z′-axis side to the principal surface 351, and a side surface 353 located on the −Z′-axis side to the principal surface 351. The side surface 352 is a first crystal face of the quartz crystal, and is a plane (i.e., a plane roughly parallel to the Y′ axis) roughly perpendicular to the principal surface 351. In contrast, the side surface 353 is a second crystal face of the quartz crystal, and is a plane oblique to the principal surface 351.

Similarly to the above, the second protruding section 37 has a principal surface 371, a side surface 372 located on the −Z′-axis side to the principal surface 371, and aside surface 373 located on the +Z′-axis side to the principal surface 371. The side surface 372 is a first crystal face of the quartz crystal, and is a plane (i.e., a plane roughly parallel to the Y′ axis) roughly perpendicular to the principal surface 371. In contrast, the side surface 373 is a second crystal face of the quartz crystal, and is a plane oblique to the principal surface 371.

It should be noted that the fact that the side surface 353 is roughly perpendicular to the principal surface 351 denotes that an angle θ formed between the principal surface 351 and the side surface 353 is included in a range of 85°≦θ≦95°. Similarly, the fact that the side surface 373 is roughly perpendicular to the principal surface 371 denotes that an angle θ formed between the principal surface 371 and the side surface 373 is included in a range of 85°≦θ≦95°.

Further, an end (a boundary between the principal surface 351 and the side surface 352) A1 on the +Z′-axis side of the principal surface 351 of the first protruding section 35 is located so as to overlap the principal surface 371 of the second protruding section 37. In other words, the end A1 is located between an end (a boundary between the principal surface 371 and the side surface 372) A3 on the −Z′-axis side of the principal surface 371 of the second protruding section 37 and an end (a boundary between the principal surface 371 and the side surface 373) A4 on the +Z′-axis side thereof in the Z′-axis direction.

Further, the end A3 on the −Z′-axis side of the principal surface 371 of the second protruding section 37 is located so as to overlap the principal surface 351 of the first protruding section 35 in a plan view. In other words, the end A3 is located between the end A1 on the +Z′-axis side of the principal surface 351 of the first protruding section 35 and an end (a boundary between the principal surface 351 and the side surface 353) A2 on the −Z′-axis side thereof in a plan view in the Z′-axis direction. Further, the end A3 is located away from the end A1 in the −Z-axis direction.

By arranging the ends A1, A3 as described above, the resonator element 2 quality control of which is easy can be obtained. Hereinafter, the specific explanation will be presented. Firstly, as one of the factors for determining the frequency characteristics of the resonator element 2, there can be cited the width (the length in the Z′-axis direction) W1 of an effective vibrating region 39 of the vibrating section 31. It should be noted that the effective vibrating region 39 denotes a region where the principal surface 351 of the first protruding section 35 of the vibrating section 31 and the principal surface 371 of the second protruding section 37 overlap each other in a plan view. Therefore, by measuring and then controlling the width W1 of the effective vibrating region 39, the controller (e.g., the manufacturer) can perform sorting by determining those having the width W1 within a predetermined numerical range as non-defective elements and those having the width W1 out of the predetermined numerical range as defective elements, or can select the purpose of use depending on the value of the width W1.

A method of measuring the width W1 of the effective vibrating region 39 is not particularly limited, but there are various methods. As a relatively easy and accurate method, the following method can be cited. Specifically, the width W1 can easily be obtained by measuring the total width (the length in the Z′-axis direction) of the quartz crystal substrate 3 as W2, measuring the distance between an end B1 on the +Z′-axis direction of the quartz crystal substrate 3 and the end A1 on the +Z′-axis side of the principal surface 351 of the first protruding section 35 as L1, measuring the distance between an end B2 on the −Z′-axis side of the quartz crystal substrate 3 and the end A3 on the −Z′-axis side of the principal surface 371 of the second protruding section 37 as L2, and then substituting the values of W2, L1, and L2 thus measured to the following formula.

W1=W2−(L1+L2)

Here, the measurement of the distance L1 is performed using the end A1 as a reference. The end A1 is the boundary between the principal surface 351 and the side surface 352 of the first protruding section 35. Since the side surface 352 is a surface roughly perpendicular to the principal surface 351, the boundary C1 between the side surface 352 and the peripheral section 32 overlaps the end A1 when viewing the resonator element 2 from the upper side (the +Y′-axis side), and is therefore not visually recognized as shown in FIG. 5A. Therefore, since no line segments or the like hindering the visual recognition of the end A1 appear around the end A1, the end A1 can accurately be identified, and thus the distance L1 can accurately be measured.

Similarly, the measurement of the distance L2 is performed using the end A3 as a reference. The end A3 is the boundary between the principal surface 371 and the side surface 372 of the second protruding section 37. Since the side surface 372 is a surface roughly perpendicular to the principal surface 371, the boundary C2 between the side surface 372 and the peripheral section 32 overlaps the end A3 when viewing the resonator element 2 from the lower side (the −Y′-axis side), and is therefore not visually recognized as shown in FIG. 5B. Therefore, since no line segments or the like hindering the visual recognition of the end A3 appear around the end A3, the end A3 can accurately be identified, and thus the distance L2 can accurately be measured.

As described above, according to the resonator element 2, it is possible to accurately measure the distances L1, L2, and thus, the width W1 can accurately be obtained. Therefore, it is possible to easily perform the highly accurate quality control based on the value of the width W1.

It should be noted that when assuming that the distance between the end A1 of the principal surface 351 of the first protruding section 35 and the end A4 of the principal surface 371 of the second protruding section 37 is D1, the distance between the end A3 of the principal surface 371 of the second protruding section 37 and the end A2 of the principal surface 351 of the first protruding section 35 is D2, and the sum of the height t1 from a principal surface 32a of the peripheral section to the principal surface of the first protruding section 35 and the height t2 from a principal surface 32b of the peripheral section to the principal surface of the second protruding section 37 is t in a plan view, it is preferable to satisfy both of the following conditions.

0<D1≦t/2

0<D2≦t/2

Thus, it is possible to obtain the width W1 using the method described above while keeping the effective vibrating region 39 larger in size. Therefore, it is possible to obtain the resonator element 2 easily controlled while exerting superior vibration characteristics.

Further, the distances D1, D2 can be different from each other, but are preferably equal to each other. Thus, it is possible to roughly match the center of the quartz crystal substrate 3 in the Z′-axis direction and the center of the effective vibrating region 39 in the Z′-axis direction each other. In other words, it is possible to suppress the displacement of the center of the effective vibrating region 39 in the Z′-axis direction from the center of the quartz crystal substrate 3 in the Z′-axis direction. Therefore, since it is possible to vibrate the vibrating section 31 (the effective vibrating region 39) in a balanced manner, superior vibration characteristics can be exerted.

Further, the height t1 and the height t2 can be different from each other, but are preferably equal to each other. Thus, since it is possible to vibrate the vibrating section 31 (the effective vibrating region 39) in a balanced manner, superior vibration characteristics can be exerted.

Further, since the end A1 of the principal surface 351 of the first protruding section 35 is located on the +Z′-axis side and the end A3 of the principal surface 371 of the second protruding section 37 is located on the −Z′-axis side with respect to the center O1 of the quartz crystal substrate 3 in the Z′-axis direction as in the present embodiment, the effective vibrating region 39 can be formed at the central portion in the Z′-axis direction of the quartz crystal substrate 3 in a balanced manner. Therefore, it is possible to vibrate the vibrating section 31 in a balanced manner.

### 2. Method of Manufacturing Resonator Element

Then, a method of manufacturing the resonator element 2 (the manufacturing method according to the embodiment of the invention) will be explained with reference to FIGS. 6A through 6C, and 7.

The method of manufacturing the resonator element 2 has a first process of preparing an AT-cut quartz crystal substrate 30, a second process of providing the quartz crystal substrate 30 with the vibrating section 31 and the peripheral section 32 to thereby obtain the quartz crystal substrate 3, and a third process of providing the quartz crystal substrate 3 with the conductive pattern 4. Further, the second process includes a mask forming process of forming the first mask M1 corresponding to the first protruding section 35 on the principal surface on the +Y′-axis side of the quartz crystal substrate 30, and at the same time forming the second mask M2 corresponding to the second protruding section 37 on the principal surface on the −Y′-axis side, and an etching process of etching the quartz crystal substrate 30 via the first mask M1 and the second mask M2.

Hereinafter, each of these processes will sequentially be explained in detail.

### First Process

Firstly, as shown in FIG. 6A, the quartz crystal substrate 30 carved out with AT-cut is prepared. The quartz crystal substrate 30 is a member, which turns out the quartz crystal substrate 3 after passing through the processes described later.

### Second Process

### Mask Forming Process

Firstly, as shown in FIG. 6B, the first mask M1 is formed on the upper surface of the quartz crystal substrate 30, and at the same time the second mask M2 is formed on the lower surface thereof using a photolithography method or the like. The first mask M1 is formed so as to correspond to the first protruding section 35 provided to the vibrating section 31, and the second mask M2 is formed so as to correspond to the second protruding section 37. It should be noted that the first mask M1 and the second mask M2 have the same shape (including the size) as each other.

Further, as shown in FIG. 6B, the first mask M1 and the second mask M2 are shifted from each other in the Z′-axis direction. Specifically, the first and second masks M1, M2 are formed so that the first mask M1 is located on the −Z′-axis side of the second mask M2.

Further, the first mask M1 is formed so that the center O2 thereof in the Z′-axis direction is located on the −Z′-axis side of the center O1 of the quartz crystal substrate 30 in the Z′-axis direction, and the second mask M2 is formed so that the center O3 thereof in the Z′-axis direction is located on the +Z′-axis side of the center O1.

Further, it is arranged that the distance D3 between the center O1 and the center O2 and the distance D4 between the center O1 and the center O3 are roughly equal to each other. The displacement amount (a distance D5 between the center O2 and the center O3) between the first and second masks M1, M2 in the Z′-axis direction is not particularly limited, but preferably satisfies the following condition assuming that the sum of the height t1 of the first protruding section 35 to be formed and the height t2 of the second protruding section 37 is t.

0<D5≦t/2

### Etching Process

Subsequently, the quartz crystal substrate 30 is etched via the first and second masks M1, M2. The etching method is not particularly limited, but a wet-etching method can be used. Thus, as shown in FIG. 6C, there can be obtained the quartz crystal substrate 3 having the vibrating section 31 having the first protruding section 35 and the second protruding section 37, and the peripheral section 32 formed in the periphery of the vibrating section 31.

Since the quartz crystal substrate 30 is side-etched in the −Z′-axis direction, the side surface 352 of the first protruding section 35 is formed at a position where the quartz crystal substrate 30 is eroded inward (toward the −Z′-axis side) from the end on the +Z′-axis side of the first mask M1. Further, the side surface 352 appears as a vertical surface roughly perpendicular to the principal surface 351 of the first protruding section 35. In contrast, the side surface 353 of the first protruding section 35 appears as a tilted surface tilted toward the −Z′-axis side from the end on the −Z′-axis side of the first mask M1.

Similarly, since the quartz crystal substrate 30 is side-etched in the +Z′-axis direction, the side surface 372 of the second protruding section 37 is formed at a position where the quartz crystal substrate 30 is eroded inward (toward the +Z′-axis side) from the end on the −Z′-axis side of the second mask M2. Further, the side surface 372 appears as a vertical surface roughly perpendicular to the principal surface 371 of the second protruding section 37. In contrast, the side surface 373 of the second protruding section 37 appears as a tilted surface tilted toward the +Z′-axis side from the end on the +Z′-axis side of the second mask M2.

Further, the end A1 of the principal surface 351 of the first protruding section 35 is located so as to overlap the principal surface 371 of the second protruding section 37 in the Y′-axis direction. In other words, the end A1 is located between the both ends A3, A4 of the principal surface 371 of the second protruding section 37 in the Z′-axis direction. Further, the end A3 of the principal surface 371 of the second protruding section 37 is located so as to overlap the principal surface 351 of the first protruding section 35 in the Y′-axis direction. In other words, the end A3 is located between the both ends A1, A2 of the principal surface 351 of the first protruding section 35 in the Z′-axis direction.

Further, the end A3 is located away from the end A1 toward the −Z′-axis side. Further, the end A1 is located on the +Z′-axis side of the center O1 of the quartz crystal substrate 30 (the quartz crystal substrate 3), and the end A3 is located on the −Z′-axis side of the center O1.

### Third Process

After removing the first and second masks M1, M2, the conductive pattern 4 (the first and second excitation electrodes 411, 412, the first and second connection electrodes 421, 422, and first and second connection wiring lines 431, 432) is formed on the quartz crystal substrate 3 as shown in FIG. 7. Specifically, the conductive pattern 4 can be formed by, for example, firstly depositing films of Cr (chromium) and Au (gold) in this order on the quartz crystal substrate 3 using a vapor phase deposition method such as evaporation, sputtering, ion plating, PVD, or CVD, then forming a mask corresponding to the conductive pattern 4 on the film using the photolithography method or the like, then patterning the film using a dry-etching method or the like, and then removing the mask.

The resonator element 2 can be obtained through the process described above.

In particular, since in the manufacturing method described above the displacement amount D5 between the first and second masks satisfies the following relationship, it is possible to surely position the end A1 of the principal surface 351 of the first protruding section 35 so as to overlap the principal surface 371 of the second protruding section 37 in the Y′-axis direction, and to surely position the end A3 of the principal surface 371 of the second protruding section 37 so as to overlap the principal surface 351 of the first protruding section 35 in the Y′-axis direction.

0<D5≦t/2

Further, it is possible to prevent the ends A1, A3 from coming too closer to each other to thereby keep the effective vibrating region 39 large in size.

Further, in the manufacturing method described above, since the first mask M1 is formed so that the center O2 thereof is located on the −Z′-axis side of the center O1 of the quartz crystal substrate 30, and the second mask M2 is formed so that the center O3 thereof is located on the +Z′-axis side of the center O1, it is possible to form the effective vibrating region 39 at the center portion of the quartz crystal substrate 3 in the Z′-axis direction. Therefore, it is possible to vibrate the vibrating section 31 in a balanced manner.

It should be noted that by housing the resonator element 2 obtained in such a manner as described above in the package 9, the resonator 1 can be obtained. Specifically, the base 91 provided with the first and second connection terminals 95, 96, the external terminals 94, 97, and the through holes is prepared, and the resonator element 2 is fixed to the base 91 via the electrically conductive fixation sections 71, 72. Subsequently, the lid 92 and the base 91 are bonded to each other so as to block the upper opening of the base 91 with the lid 92. Thus, the resonator 1 can be obtained.

### Second Embodiment

Then, another resonator according to a second embodiment of the invention will be explained.

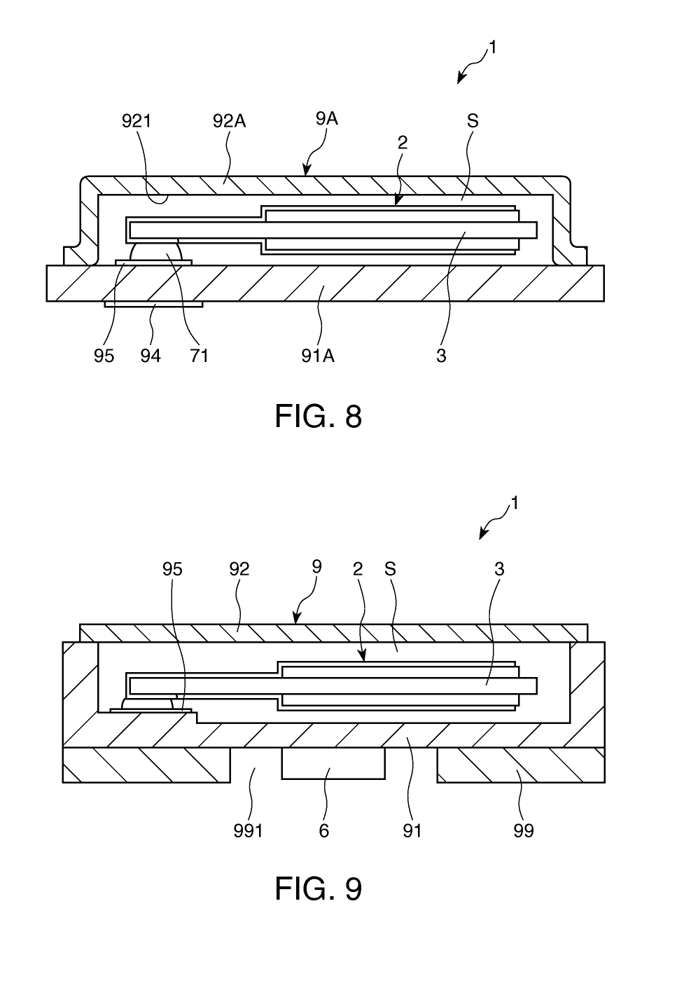

FIG. 8 is a cross-sectional view of the resonator according to the second embodiment of the invention.

Hereinafter, the resonator according to the second embodiment will be described with a focus mainly on the differences from the first embodiment described above, and the explanation regarding substantially the same matters will be omitted.

The resonator according to the second embodiment of the invention is substantially the same as that of the first embodiment described above except the point that the configuration of the package is different. It should be noted that the constituents substantially the same as those of the first embodiment described above are denoted with the same reference symbols.

As shown in FIG. 8, the package 9A has a base 91A having a plate shape (flat plate shape), and a lid 92A having a cap-like shape with a recessed section 921 opening downward. Such a package 9A forms the housing space S with the base 91A blocking the opening of the recessed section 921, and airtightly houses the resonator element 2 in the housing space S.

According also to the second embodiment described above, substantially the same advantages as in the first embodiment described above can be obtained.

### Third Embodiment

Then, another resonator according to a third embodiment of the invention will be explained.

FIG. 9 is a cross-sectional view of the resonator according to the third embodiment of the invention.

Hereinafter, the resonator according to the third embodiment will be described with a focus mainly on the differences from the first embodiment described above, and the explanation regarding substantially the same matters will be omitted.

The resonator according to the third embodiment of the invention is substantially the same as that of the first embodiment described above except the point that the configuration of the package is different, and further, an electronic component is provided. It should be noted that the constituents substantially the same as those of the first embodiment described above are denoted with the same reference symbols.

As shown in FIG. 9, the resonator 1 according to the present embodiment has the resonator element 2, the package 9 for housing the resonator element 2, and a thermosensing component (the electronic component) 6 for detecting the temperature of the resonator element 2.

Further, the package 9 has a housing section 991 for housing the thermosensing component 6. The housing section 991 can be formed by, for example, disposing a frame-like member 99 on the bottom side of the base 91.

As the thermosensing component 6, there can be used, for example, a thermistor having a physical quantity such as an electrical resistance varying in accordance with the temperature variation. Further, by detecting the electrical resistance of the thermistor with an external circuit, the detected temperature of the thermistor can be measured.

According also to the third embodiment described above, substantially the same advantages as in the first embodiment described above can be obtained.

Hereinabove, the resonator element and the resonator according to the embodiment of the invention are explained. It should be noted that although the configuration of housing the resonator element alone in the housing space S is explained as the configuration of the resonator described above, it is also possible to additionally house other electronic components in the housing space S. As such electronic components, there can be cited, for example, a temperature detection element such as a thermistor for detecting the temperature of the resonator element, and an IC chip 8 described later for controlling drive of the resonator element 2.

### Oscillator

Then, the oscillator (the oscillator according to the embodiment of the invention) to which the resonator element according to the embodiment of the invention is applied will be explained.

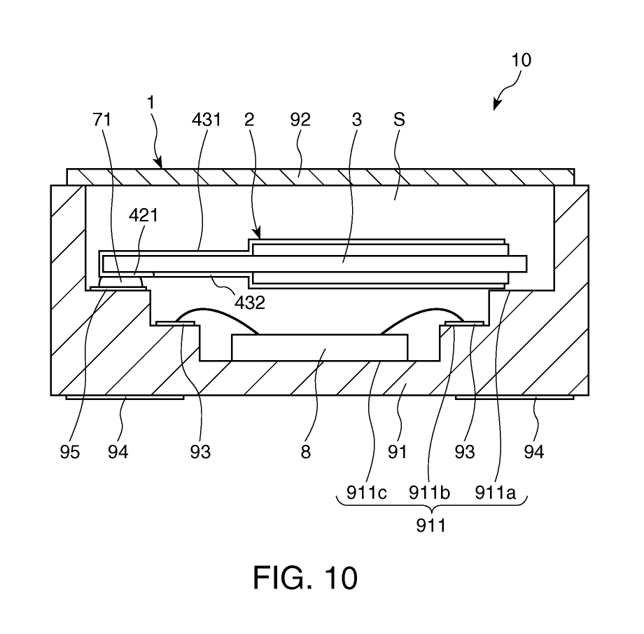

The oscillator 10 shown in FIG. 10 has the resonator 1 and the IC chip (a chip part) 8 for driving the resonator element 2. Hereinafter, the oscillator 10 will be explained with a focus mainly on the differences from the resonator described above, and the explanations regarding substantially the same matters will be omitted.

The package 9 has the base 91 having a box shape provided with the recessed section 911, and the lid 92 having a plate shape for blocking the opening of the recessed section 911.

The recessed section 911 of the base 91 has a first recessed section 911a opened in the upper surface of the base 91, a second recessed section 911b opened in a center portion of the bottom surface of the first recessed section 911a, and a third recessed section 911c opened in a center portion of the bottom surface of the second recessed section 911b.

On the bottom surface of the first recessed section 911a, there are formed the first connection terminal 95 and the second connection terminal 96. Further, on the bottom surface of the third recessed section 911c, there is disposed the IC chip 8. The IC chip 8 has a drive circuit (an oscillation circuit) for controlling drive of the resonator element 2. By driving the resonator element 2 with the IC chip 8, a signal with a predetermined frequency can be taken out.

Further, on the bottom surface of the second recessed section 911b, there is formed a plurality of internal terminals 93 electrically connected to the IC chip 8 via wires. The plurality of internal terminals 93 includes a terminal electrically connected to the external terminal (the mounting terminal) 94 formed on the bottom surface of the package 9 via a through hole not shown provided to the base 91, a terminal electrically connected to the first connection terminal 95 via a through hole and a wire not shown, and a terminal electrically connected to the second connection terminal 96 via a through hole and a wire not shown.

It should be noted that although the configuration having the IC chip 8 disposed in the housing space S is explained with reference to FIG. 10, the arrangement of the IC chip 8 is not particularly limited, but it is also possible to dispose the IC chip 8, for example, outside (on the bottom surface of) the package 9.

### Electronic Apparatuses

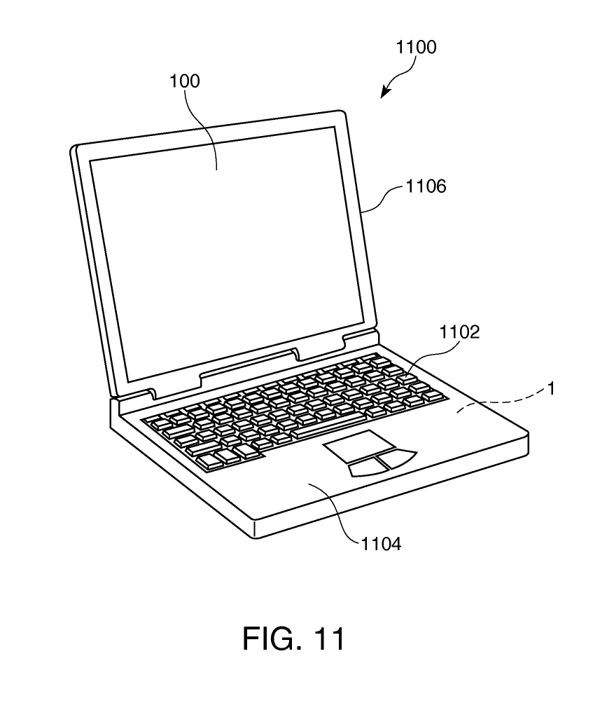

Then, the electronic apparatuses (the electronic apparatuses according to the embodiment of the invention) to which the resonator element according to the embodiment of the invention is applied will be explained in detail with reference to FIGS. 11 through 13.

FIG. 11 is a perspective view showing a configuration of a mobile type (or laptop type) of personal computer as an example of the electronic apparatus equipped with the resonator element according to the embodiment of the invention. In the drawing, the personal computer 1100 is composed of a main body section 1104 provided with a keyboard 1102, and a display unit 1106 provided with a display section 100, and the display unit 1106 is pivotally supported with respect to the main body section 1104 via a hinge structure. Such a personal computer 1100 incorporates the resonator 1 functioning as a filter, a resonator, a reference clock, and so on.

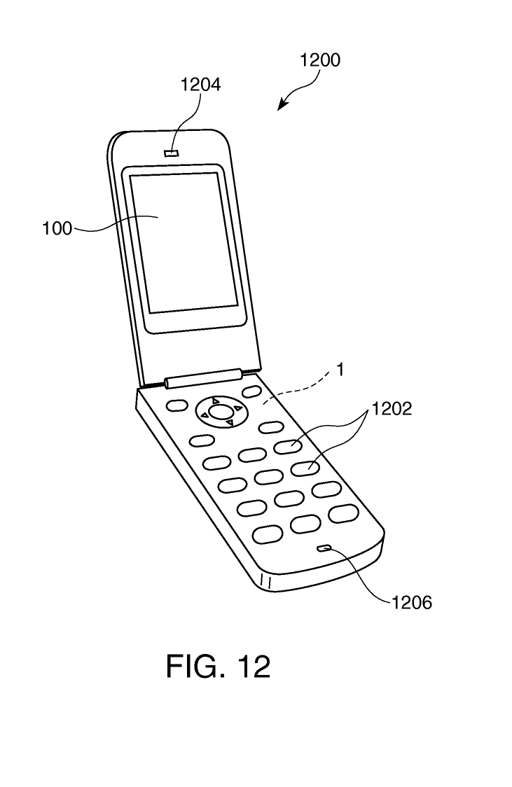

FIG. 12 is a perspective view showing a configuration of a cellular phone (including PHS) as an example of the electronic apparatus equipped with the resonator element according to the embodiment of the invention. In this drawing, the cellular phone 1200 is provided with a plurality of operation buttons 1202, an ear piece 1204, and a mouthpiece 1206, and the display section 100 is disposed between the operation buttons 1202 and the ear piece 1204. Such a cellular phone 1200 incorporates the resonator 1 functioning as a filter, a resonator, and so on.

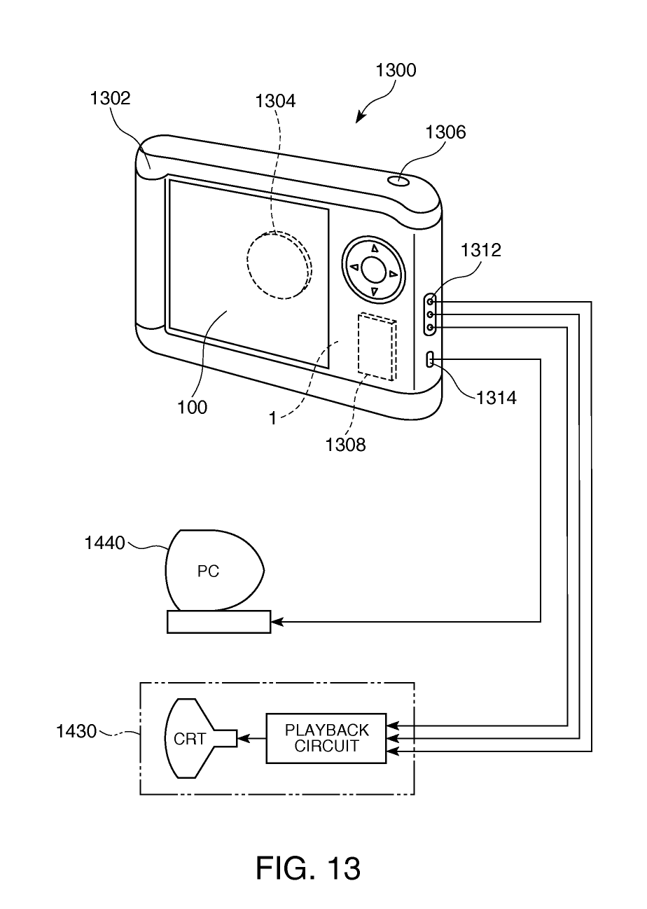

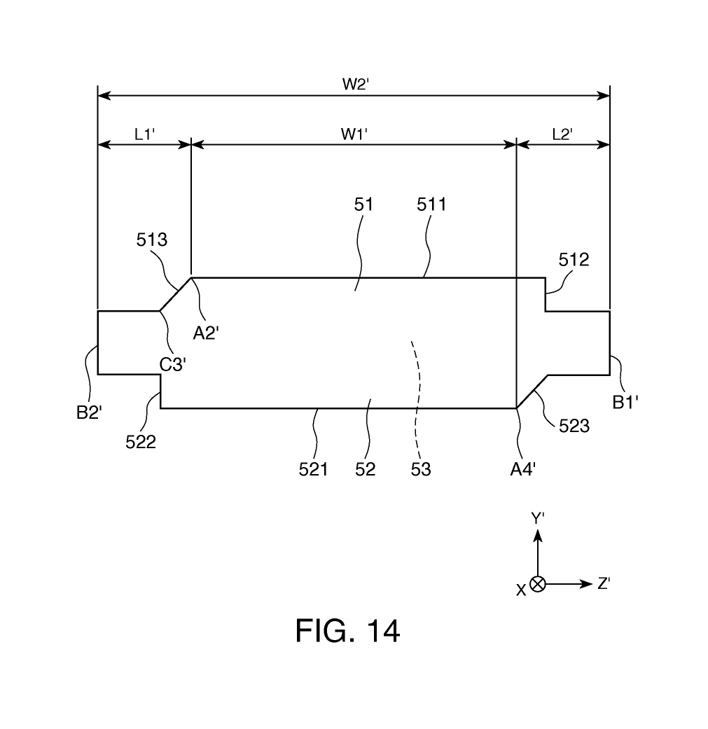

FIG. 13 is a perspective view showing a configuration of a digital still camera as an example of the electronic apparatus equipped with the resonator element according to the embodiment of the invention. It should be noted that connection with external equipment is also shown schematically in this drawing. Here, existing cameras expose a silver salt film to an optical image of an object, while the digital still camera 1300 performs photoelectric conversion on an optical image of an object by an imaging element such as a CCD (a charge coupled device) to generate an imaging signal (an image signal).

The case (body) 1302 of the digital still camera 1300 is provided with a display section on the back surface thereof to be configured to display an image in accordance with the imaging signal from the CCD, wherein the display section functions as a viewfinder for displaying the object as an electronic image. Further, the front surface (the back side in the drawing) of the case 1302 is provided with a light receiving unit 1304 including an optical lens (an imaging optical system), the CCD, and so on.

When the photographer confirms an object image displayed on the display section, and then pushes a shutter button 1306 down, the imaging signal from the CCD at that moment is transferred to and stored in the memory device 1308. Further, the digital still camera 1300 is provided with video signal output terminals 1312 and an input-output terminal 1314 for data communication disposed on a side surface of the case 1302. Further, as shown in the drawing, a television monitor 1430 and a personal computer 1440 are respectively connected to the video signal output terminals 1312 and the input-output terminal 1314 for data communication according to needs. Further, there is adopted the configuration in which the imaging signal stored in the memory device 1308 is output to the television monitor 1430 or the personal computer 1440 in accordance with a predetermined operation. Such a digital still camera 1300 incorporates the resonator 1 functioning as a filter, a resonator, and so on.

It should be noted that, as the electronic apparatus equipped with the resonator element according to the embodiment of the invention, there can be cited, for example, an inkjet ejection device (e.g., an inkjet printer), a laptop personal computer, a television set, a video camera, a video cassette recorder, a car navigation system, a pager, a personal digital assistance (including one with communication function), an electronic dictionary, an electric calculator, a computerized game machine, a word processor, a workstation, a video phone, a security video monitor, a pair of electronic binoculars, a POS terminal, a medical device (e.g., an electronic thermometer, an electronic manometer, an electronic blood sugar meter, an electrocardiogram measurement instrument, an ultrasonograph, and an electronic endoscope), a fish detector, various types of measurement instruments, various types of gauges (e.g., gauges for a vehicle, an aircraft, or a ship), and a flight simulator besides the personal computer (the mobile personal computer) shown in FIG. 11, the cellular phone shown in FIG. 12, and the digital still camera shown in FIG. 13.

Although the resonator element, the resonator, the oscillator, and the electronic apparatus according to the embodiment of the invention are hereinabove explained based on the embodiments shown in the accompanying drawings, the invention is not limited thereto, but the configuration of each of the constituents can be replaced with one having an arbitrary configuration with an equivalent function. Further, it is possible to add any other constituents to the invention. Further, it is also possible to arbitrarily combine any of the embodiments.

The entire disclosure of Japanese Patent Application No. 2012-059329, filed Mar. 15, 2012 is expressly incorporated by reference herein.

What is claimed is:

1. A method of manufacturing a resonator element, comprising:
providing a rotated Y-cut quartz crystal substrate;
forming a mesa substrate by
disposing a first mask on a principal surface located on a +Y′-axis side of the quartz crystal substrate,
disposing a second mask on a principal surface located on a −Y′-axis side so as to be located at a position shifted toward a +Z′-axis side from the first mask, and
etching the quartz crystal substrate via the first mask and the second mask,
the mesa substrate including
a vibrating section including
a first protruding section protruding toward the +Y′-axis side from the quartz crystal substrate and
a second protruding section protruding toward the −Y′-axis side, and
a small-thickness section disposed along an outer edge of the vibrating section and having a thickness smaller than a thickness of the vibrating section; and
providing a conductive pattern to the mesa substrate.

2. The method of manufacturing a resonator element according to claim 1, wherein
an end on the +Z′-axis side of the first mask is located on the +Z′-axis side with respect to a center of the mesa substrate in a Z′-axis direction, and
an end on the −Z′-axis side of the second mask is located on the −Z′-axis side with respect to the center of the mesa substrate in the Z′-axis direction.

3. The method of manufacturing a resonator element according to claim 1, wherein
assuming that a shift amount in the Z′-axis direction between the first mask and the second mask is D, and a sum of a height of the principal surface of the first protruding section from a principal surface on the +Y′-axis side of the small-thickness section and a height of the principal surface of the second protruding section from a principal surface on the −Y′-axis side of the small-thickness section is t,
a relationship between the shift amount D and the sum t satisfies 0<D≦t/2.

4. The method of manufacturing a resonator element according to claim 1, wherein
a side surface connecting the end on the +Z′-axis side of the principal surface of the first protruding section and the small-thickness section to each other is perpendicular to the principal surface of the first protruding section, and
a side surface connecting the end on the −Z′-axis side of the principal surface of the second protruding section and the small-thickness section to each other is perpendicular to the principal surface of the second protruding section.

5. The method of manufacturing a resonator element according to claim 1, wherein
the quartz crystal substrate is an AT-cut quartz crystal substrate.

6. A method of manufacturing a resonator, comprising:
housing the resonator element manufactured using the method of manufacturing a resonator element according to claim 1 in a package.

7. A resonator element comprising:
a rotated Y-cut quartz crystal substrate including
a vibrating section including
a first protruding section protruding toward a +Y′-axis side and
a second protruding section protruding toward a −Y′-axis side, and
a small-thickness section disposed along an outer edge of the vibrating section and having a thickness smaller than a thickness of the vibrating section; and
a conductive pattern provided to the quartz crystal substrate,
wherein an end on a +Z′-axis side of a principal surface of the first protruding section is disposed so as to overlap a principal surface of the second protruding section in a plan view in a Y′-axis direction, and
an end on a −Z′-axis side of the principal surface of the second protruding section overlaps the principal surface of the first protruding section in the plan view in the Y′-axis direction.

8. A resonator comprising:
the resonator element according to claim 7; and
a package adapted to house the resonator element.

9. An oscillator comprising:
the resonator element according to claim 7; and
an oscillation circuit electrically connected to the resonator element.

10. An electronic apparatus comprising:
the resonator element according to claim 7.
